(19) United States
(12) Patent Application Publication
(10) Pub. No.: US 2010/0206163 A1
(43) Pub. Date: Aug. 19, 2010

(54) WEAR RESISTANCE REINFORCING METHOD AND SLIDING STRUCTURE

(76) Inventors: Tomofumi Mizutani, Yokohama-shi (JP); Keiji Okada, Tokyo (JP)

Correspondence Address: OSTROLENK FABER GERB & SOFFEN, 1180 AVENUE OF THE AMERICAS, NEW YORK, NY, 100368403, US

(21) Appl. No.: 12/738,927

(22) PCT Filed: Oct. 22, 2008
(86) PCT No.: PCT/JP2008/069123

§ 371 Date: Apr. 20, 2010

(30) Foreign Application Priority Data
Oct. 24, 2007 (JP) 2007-276396

(51) Int. Cl. F16J 10/04; C23C 4/12; C23C 16/44

(52) U.S. Cl. 92/169.1; 427/456; 427/249.7

(57) ABSTRACT

A wear resistance reinforcing method for a sliding structure formed from at least a pair of components in a sliding relation and provided with a seal member on a sliding face of a first component. A wear-resistant metal-plated film formed from a metal having a predetermined reactivity with the material of the seal member is provided on a sliding surface of a second component. The present invention enables provision of a wear resistance reinforcing method and a sliding structure which improves workability of a film to impart wear resistance properties in addition to low unevenness in wear resistance properties.

### TECHNICAL FIELD

The present invention relates to a wear resistance reinforcing method and a sliding structure. The present application claims priority from Japanese Patent Application No. 2007-276396 filed in Japan on Oct. 24, 2007 and the disclosure of the contents of that application is incorporated herein by reference in its entirety.

### BACKGROUND ART

Various types of aircraft actuators are provided on a single sliding structure. An aircraft actuator slides on a bearing in a cylindrical housing and includes a piston connected with a piston rod (drive shaft). An aircraft actuator is characterized in that aircraft fuel is often used to drive the actuator rather than using working oil having dedicated lubrication characteristics. Since the weight of an aircraft must be reduced as much as possible, an actuator is frequently driven using fuel oil which is always provided in the aircraft rather than providing dedicated driving lubrication oil to the aircraft. Consequently, since an aircraft actuator is driven using aircraft fuel which has inferior lubrication characteristics in comparison with lubrication oil, the actuator sliding face tends to wear in comparison to a general actuator driven using lubrication oil.

To resolve problems associated with the above type of wear resistance, the sliding surfaces of a conventional aircraft actuator are plated by using Cr plating or nonelectrolytic Ni plating, or a film of WC—Co (tungsten carbide-cobalt) is formed on the sliding surface by using high-speed flame spraying. Film-forming techniques have attempted to form hard thin films such as chromium nitrate (CrN) or diamond-like carbon (DLC) by using chemical vapor deposition (CVD) or physical vapor deposition (PVD).

Although the present applicants have conducted a survey of prior-art literature related to wear resistance properties of aircraft actuators, a suitable solution was not identified. Patent documents 1-3 below are provided as prior-art patent literature related to the wear resistance properties of mechanical components which differ from aircraft actuators.
[Patent Document 1] Japanese Patent Application, First Publication No. 3-51576
[Patent Document 2] Japanese Patent No. 3454232
[Patent Document 3] Japanese Patent Application, First Publication No. 2001-289330

### DISCLOSURE OF THE INVENTION

### [Problem to be Solved by the Invention]

However, since plating methods using Cr plating or nonelectrolytic Ni plating require finishing processing of the plated surface, workability is poor, costs are high and wear resistance properties are also inferior to the spraying. Since a method forming a WC—Co film by using high-speed flame spraying requires spraying WC—Co onto an inner peripheral surface of a housing and a finishing processing of the film surface, workability is poor and costs are high. A method of manufacturing a hard film by using CVD or the like does not enable a stable hard film surface and causes unevenness in wear resistance properties.

The present invention is proposed in light of the above problems and has the object of providing a wear resistance reinforcing method and a sliding structure having improved workability of the film in order to impart wear resistance properties, in addition to, having low unevenness in wear resistance properties.

### [Means for Solving the Problem]

The present invention adopts the configuration hereafter to achieve the above object.

In a first wear resistance reinforcing method according to the present invention, a wear resistance reinforcing method is provided for a sliding structure including at least a pair of components in sliding relation and having a seal member on a sliding surface of a first component. A wear-resistant metal-plated film formed from a metal having a fixed reactivity with the material of the seal member is provided on a sliding surface of a second component.

Furthermore, in a second wear resistance reinforcing method according to the present invention, the first wear resistance reinforcing method is such that the seal member is formed from a fluorine resin and the second component is formed from aluminum. A plated film formed from nonelectrolytic Ni—P—B (nickel-phosphorous-boron) is formed as an underlying plated film on the surface of the second component. A plated film formed from rhodium (Rh) is formed as a wear-resistant metal-plated film on the underlying plated film.

In a third wear resistance reinforcing method according to the present invention, the sliding structure according to the first or the second wear resistance reinforcing method is an actuator in which the second component is a hollow housing and the first component is a piston connected to a piston rod and sliding freely in the housing. The piston can be displaced by a pressure difference in working oil introduced into two spaces in the housing partitioned by the piston.

A first sliding structure according to the present invention includes at least a pair of components in a sliding relation and includes a seal member on a sliding face of the first component. A wear-resistant metal-plated film formed from a metal having a predetermined reactivity with the material forming the seal member is formed on a sliding surface of the second component.

A second sliding structure according to the present invention includes the first sliding structure in which the seal member is formed from a fluorine resin and the second component is formed from aluminum. A plated film formed from nonelectrolytic Ni—P—B (nickel-phosphorous-boron) is formed as an underlying plated film on the surface of the second component and a plated film formed from rhodium (Rh) is formed as a wear-resistant metal-plated film on the underlying plated film.

A third sliding structure according to the present invention includes the first or the second sliding structure in which the second component is a hollow housing and the first component is a piston connected to a piston rod and sliding freely in the housing. The piston can be displaced by a pressure difference in working oil introduced into two spaces in the housing partitioned by the piston.

### [Effects of the Invention]

According to the present invention, the material of the seal member and the wear-resistant metal-plated film formed from a metal having a predetermined reactivity are provided on a sliding surface of the second component. As a result, the present invention is different from a conventional film forming by using a WC—Co high-speed flame spray or forming a hard thin film such as DLC by using CVD or the like. Accordingly, workability of the film in relation to imparting wear resistance properties is improved and it is possible to reduce evenness in wear resistance properties.

### BRIEF DESCRIPTION OF THE DRAWINGS

FIG. 1 is a sectional view showing an aircraft actuator A (sliding structure) according to an embodiment of the present invention.

FIG. 2 is an expanded sectional view showing the principal portions of an aircraft actuator A according to an embodiment of the present invention.

FIG. 3 is an outer view of a test piece according to an embodiment of the present invention.

FIG. 4 is a configuration view of a test device according to an embodiment of the present invention.

FIG. 5 is a graph showing test results (comparison with a wear amount of another component) according to an embodiment of the present invention.

FIG. 6 is a graph showing test results (relationship of wear amount to surface roughness) according to an embodiment of the present invention.

### DESCRIPTION OF THE REFERENCE NUMERALS

A AIRCRAFT ACTUATOR
1 HOUSING (COMPONENT)
1a BEARING
1b SEAL MEMBER
1c PARENT MEMBER
1d ZINCATE-TREATED FILM
1e NONELECTROLYTIC Ni—P—B PLATED FILM
1f Rh PLATED FILM (WEAR-RESISTANT METAL-PLATED FILM)
2 PISTON (COMPONENT)
2a BEARING
2b SEAL MEMBER
3 PISTON ROD

### BEST MODE FOR CARRYING OUT THE INVENTION

An embodiment of the present invention is explained referring to the figures.

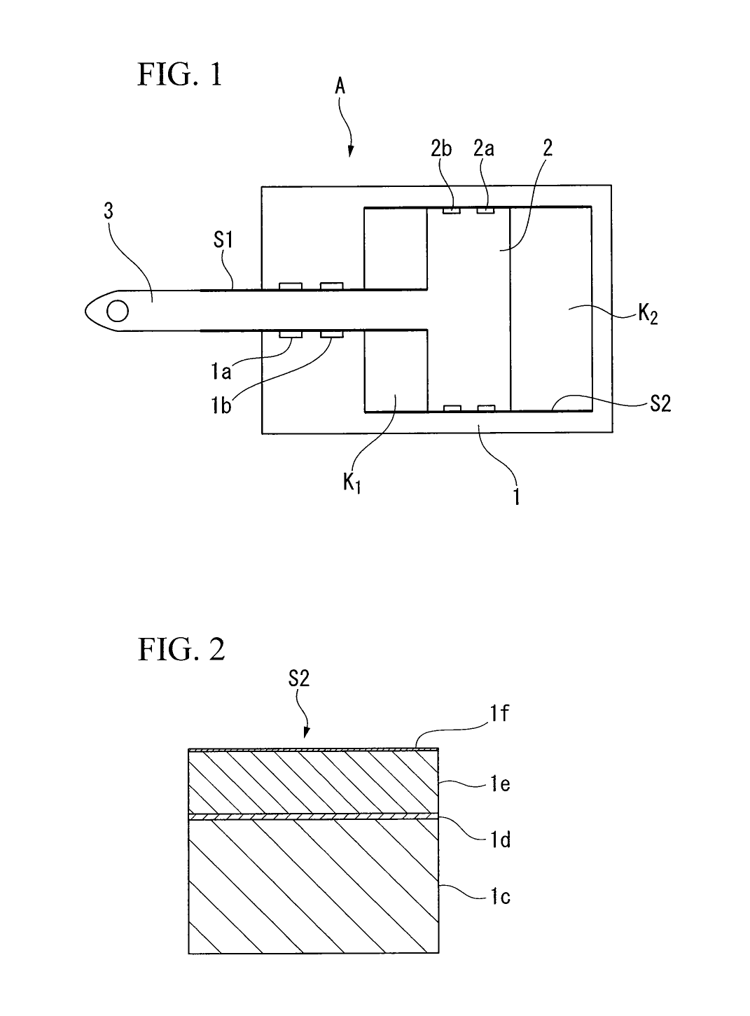

FIG. 1 is a sectional view showing an aircraft actuator A (sliding structure) according to an embodiment of the present invention.

A disk-shaped piston 2 (component) and a bar-shaped piston rod 3 (drive shaft) in an aircraft actuator A are housed in an connected orientation in a hollow cylindrical housing 1 (component). Working oil is introduced from an outer section into two spaces K1, K2 in the housing 1 partitioned by the piston 2. The piston 2 and the piston rod 3 can be displaced to the left and the right of the page surface by a pressure difference in the working oil. The housing 1 is formed from an aluminum alloy and the piston 2 and piston rod 3 as a component integrally formed from stainless steel.

In the housing 1, a bearing 1a and a seal member 1b are provided on a sliding surface (cylindrical surface) with the piston rod 3. In the piston 2, a bearing 2a and a seal member 2b are provided on a sliding surface (cylindrical surface) with the housing 1. The bearings 1a, 2a support the piston 2 and the piston rod 3, and reduce frictional resistance and are formed from resin. The seal members 1b, 2b prevent leakage of working oil and are formed from fluoride resin.

The aircraft actuator A configured in the above manner uses aircraft fuel (fuel oil) as a working oil.

In this type of aircraft actuator A, the bearing 1a and the seal member 1b of the housing 1 slide on a sliding surface S1 (cylindrical peripheral face) of the piston rod 3. The bearing 2a and the seal member 2b of the piston 2 slide on a sliding surface S2 (inner cylindrical peripheral face) of the housing 1.

FIG. 2 is an expanded sectional view of the sliding surface S2. As shown in FIG. 2, the sliding surface S2 of the housing 1 has a structure in which a zincate-treated film 1d having a thickness of 0.5 μm, a nonelectrolytic Ni—P—B (nickel-phosphorous-boron) plated film 1e having a thickness of 5.0 μm (underlying plated film) and a Rh (rhodium) plated film 1f having a thickness of 0.1 μm (finishing plated film) are laminated in sequence onto the surface of the parent member 1c formed from an aluminum alloy. The sliding surface S1 of the piston rod 3 forms only a Rh (rhodium) plated film 1f on the stainless steel forming the parent member.

The nonelectrolytic Ni—P—B plated film 1e is a plated film for reinforcing the parent member 1c formed from an aluminum alloy. Furthermore, the Rh (rhodium) plated film 1f corresponds to a wear-resistant metal-plated film in the present embodiment and is a plated film formed from Rh (rhodium) selected as a metal which has a predetermined reactivity with the seal member (fluoride resin).

The zincate-treated film 1d is formed by a zincate process which removes an oxidized film or the like on the surface of the parent member 1c and is known in the technical field of plating processes.

An aircraft actuator A configured in the above manner enables displacement of the piston 2 by introducing the working oil from an external portion into a space formed between the housing 1 and the piston 2. As a result, the sliding surface S2 of the housing 1 on which a wear resistance reinforcing film is formed slides on the bearing 2a and the seal member 2b having working oil interposed therebetween.

However, since aircraft oil is used as the working oil in the aircraft actuator A, the lubrication properties on the sliding face are inferior in comparison to use of a dedicated lubrication oil as the working oil. The Rh (rhodium) plated film 1f is provided in the aircraft actuator A to improve wear resistance properties with respect to the seal member 2b.

Generally, when fluoride resin undergoes friction with a hard material such as a metal, a film-shaped transfer film having a band structure is formed on the complementary frictional surface. Since the transfer film has excellent lubrication properties, an effect of reducing the frictional coefficient is obtained. However, the transfer film tends to peel from the frictional surface and repetition of peeling and formation is thought to result in wear of the fluoride resin.

In the present embodiment, when the seal member 2b (fluoride resin) slides on the sliding surface S2 of the housing 1, since Rh (rhodium) has a predetermined reactivity with fluoride (F), a fluoride compound (peeling-resistant transfer film) is formed on the surface of the Rh (rhodium) plated film 1f and thereby enables wear resistance properties with respect to the seal member 2b.

Experimental results related to wear resistance properties of the Rh (rhodium) plated film 1f of the aircraft actuator A is explained in detail hereafter.

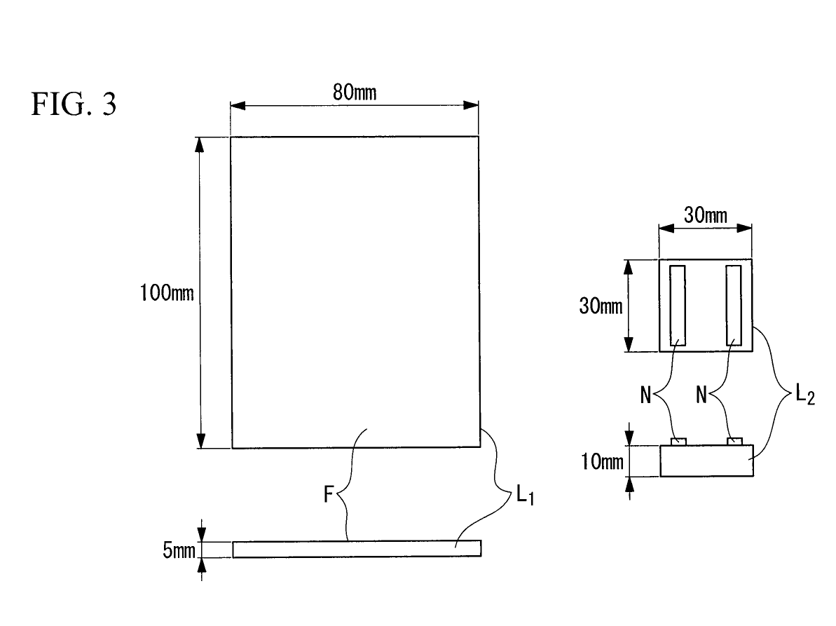

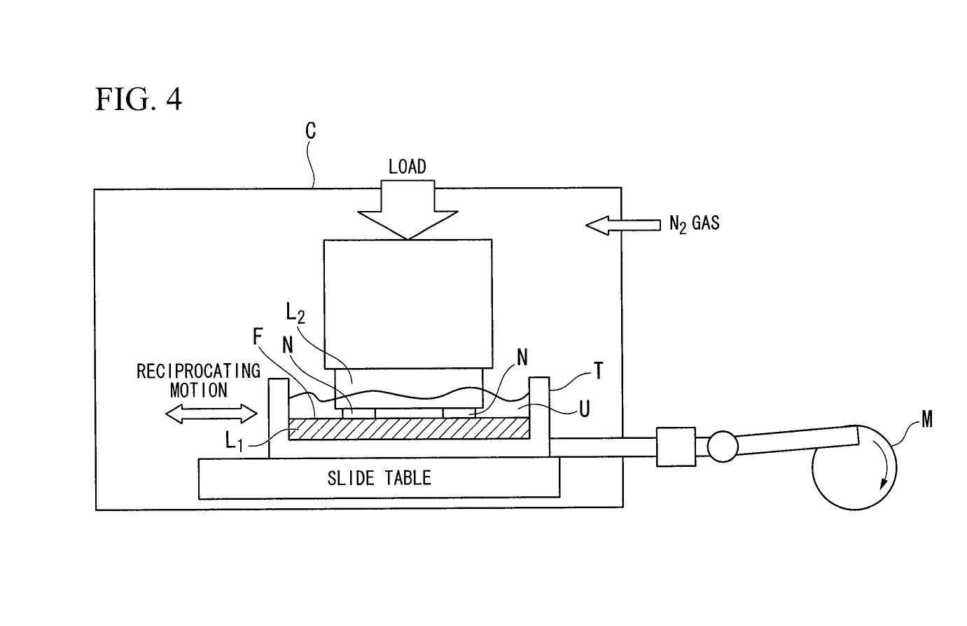

FIG. 3 is an external view of an experimental piece and FIG. 4 is a configuration view of a test device. The experimental piece is formed from a liner plate L1 (equivalent to the housing) provided with a laminated film F equivalent to the Rh (rhodium) plated film 1f on one surface of an aluminum alloy plate, and a seal block piece L2 provided with a seal member N equivalent to the seal member 2b on one surface of a stainless steel block. The liner plate L1 and the seal block piece L2 have the dimensions shown in the figures.

In the test device, the liner plate L1 is fixed to the bottom of a slide tray T so that the laminated film F is the upper surface and the seal block piece L2 is disposed so that the seal member N abuts with a predetermined load on the liner plate L1. A test oil U equivalent to the aircraft fuel (working oil) is used to fill the sliding tray T. The liner plate L1 and the seal block piece L2 undergo sliding by reciprocating the slide tray T in a horizontal direction by a motor M. In the test device, all equipment except for the drive equipment including the motor M are stored in a chamber C. As shown in the figure, a nitrogen gas (N₂ gas) atmosphere is created in the chamber C.

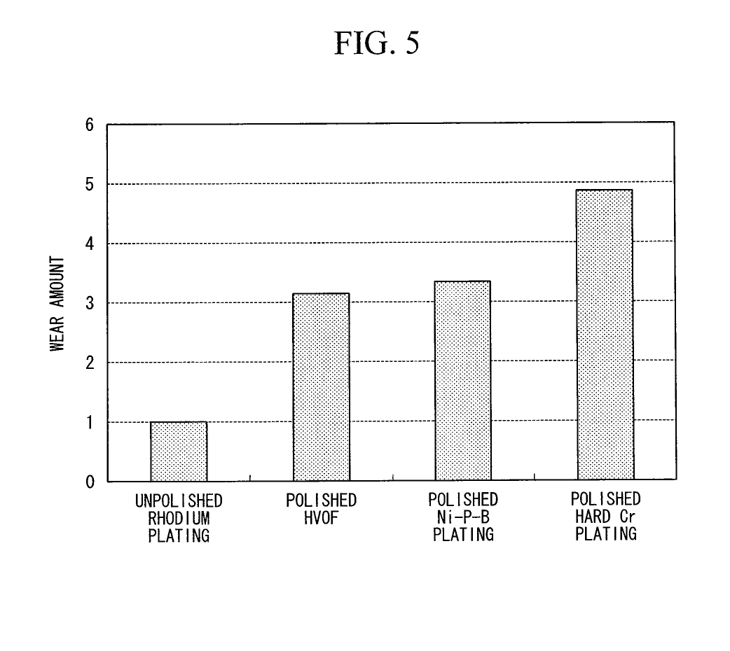

FIG. 5 is a graph showing test results (comparison with a wear amount of another component) using the above test piece and test device. The wear amount expresses a relative wear amount when the average wear amount of the rhodium plating is taken to have a value of 1. As shown in FIG. 5, use of the test device shows that the average value of the wear amount of the seal member N obtained by sliding a plurality of sliding pieces (leftmost bar graph) is at most ⅓ of the wear amount of the test piece provided with another film (HVOF film, Ni—P—B plated film or hard Cr plated film). Thus, the Rh plated film 1f of the aircraft actuator A can be confirmed to impart superior wear resistance properties to the sliding surface of the housing 1.

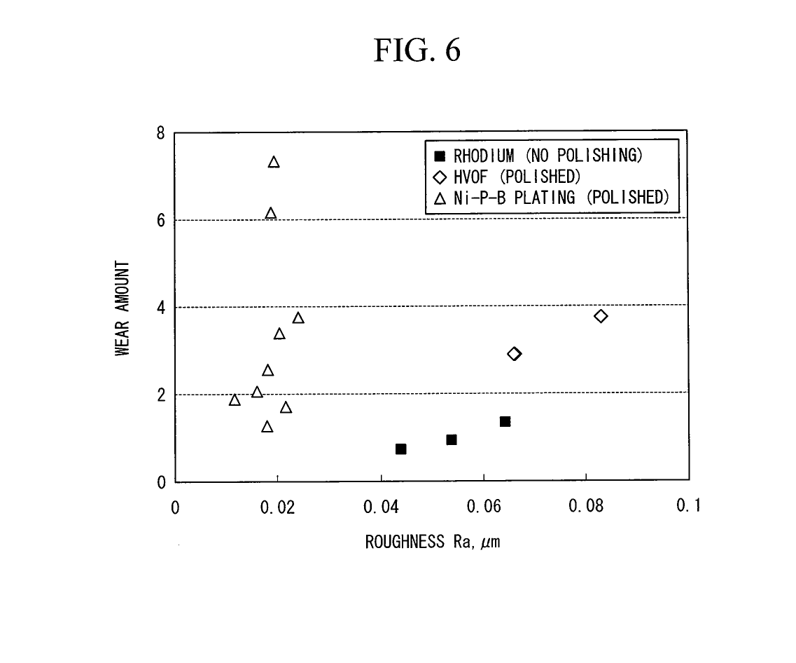

FIG. 6 is a graph showing test results (relationship of wear amount to surface roughness). The wear amount expresses the relative wear amount when the average wear amount of the rhodium plating is taken to have a value of 1. As shown in FIG. 6, the test piece (shown by the square markings) has a higher surface roughness than the test pieces (shown by the triangular markings) which have a Ni—P—B plated film in addition to a finishing polishing process. However, the wear amount of the test piece is equal to or less than the wear amount of a test piece having a Ni—P—B plated film. Thus, it can be confirmed that the Rh plated film 1f of the aircraft actuator A is not realized due to surface roughness.

The present invention is not limited to the above embodiments and, for example, may include modified examples as described below.

(1) In the above embodiment, the present invention is applied to an aircraft actuator A. However, the present invention may be applied to respective sliding structures other than an aircraft actuator A.
(2) In the above embodiment, a nonelectrolytic Ni—P—B plated film le is adopted as a reinforcing metal film and an Rh plated film 1f is adopted as a wear-resistant metal-plated film. However, the present invention is not limited thereby. A film or surface processing other than Ni—P—B may be used as the reinforcing metal film as long as it has sufficient strength to reinforce a thin member and has a high adhesion to the parent member and the wear-resistant metal-plated film. A metal other than Rh (rhodium) may be used as the wear-resistant metal-plated film as long as it is formed from a metal having a predetermined reactivity with the seal member 2b.

### INDUSTRIAL APPLICABILITY

According to the present invention, an wear-resistant metal-plated film formed from a metal having a predetermined reactivity with a material for a seal member are provided on a sliding surface of a second component. The present invention is different from a conventional film forming by using CVD or the like to form a hard thin film such as DLC or by using a WC—Co high-speed flame spray. As a result, the workability of the film in relation to imparting wear resistance is improved and it is possible to reduce unevenness in the wear resistance properties.

1. A wear resistance reinforcing method for a sliding structure formed from at least a pair of components in a sliding relation and provided with a seal member on a sliding face of a first component, wherein:
a wear-resistant metal-plated film formed from a metal having a predetermined reactivity with a material of the seal member is provided on a sliding surface of a second component.

2. The wear resistance reinforcing method according to claim 1, wherein the seal member is formed from a fluoride resin and the second component is formed from aluminum, a nonelectrolytic Ni—P—B (nickel-phosphorous-boron) plated film is formed as an underlying plated film on a surface of the second component, and a Rh (rhodium) plated film is formed as a wear-resistant metal-plated film on the underlying plated film.

3. The wear resistance reinforcing method according to claim 1, wherein the sliding structure is an actuator in which the second component is a hollow housing and the first component is a piston connected to a piston rod and sliding freely in the housing, the piston displaceable by a pressure difference in working oil introduced into two spaces in the housing partitioned by the piston.

4. The wear resistance reinforcing method according to claim 2, wherein the sliding structure is an actuator in which the second component is a hollow housing and the first component is a piston connected to a piston rod and sliding freely in the housing, the piston displaceable by a pressure difference in working oil introduced into two spaces in the housing partitioned by the piston.

5. A sliding structure comprising at least a pair of components in a sliding relation and a seal member on a sliding face of a first component, and a wear-resistant metal-plated film formed from a metal having a predetermined reactivity with the material of the seal member and formed on a sliding surface of a second component.

6. The sliding structure according to claim 5, wherein the seal member is formed from a fluorine resin and the second component is formed from aluminum, a nonelectrolytic Ni—P—B (nickel-phosphorous-boron) plated film is formed as an underlying plated film on the surface of the second component, and a rhodium (Rh) plated film is formed as a wear-resistant metal-plated film on the underlying plated film.

7. The sliding structure according to claim 5, wherein the second component is a hollow housing and the first component is a piston connected to a piston rod and sliding freely in the housing, the piston displaceable by a pressure difference in working oil introduced into two spaces in the housing partitioned by the piston.

8. The sliding structure according to claim 6, wherein the second component is a hollow housing and the first component is a piston connected to a piston rod and sliding freely in the housing, the piston displaceable by a pressure difference in working oil introduced into two spaces in the housing partitioned by the piston.
